(19) United States
(12) Patent Application Publication
(10) Pub. No.: US 2009/0170325 A1
(43) Pub. Date: Jul. 2, 2009

(54) METHOD OF FORMING A SEMICONDUCTOR DEVICE PATTERN

(75) Inventor: Woo Yung Jung, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: HYNIX SEMICONDUCTOR INC., Icheon-si (KR)

(21) Appl. No.: 12/058,615

(22) Filed: Mar. 28, 2008

(30) Foreign Application Priority Data
Dec. 28, 2007 (KR) 10-2007-140240

(51) Int. Cl. H01L 21/308

(52) U.S. Cl. 438/694; 257/E21.231

(57) ABSTRACT

In a method of forming patterns of a semiconductor device, first etch mask patterns are formed over a semiconductor substrate. An auxiliary film is formed over the first etch mask patterns to a thickness in which a step corresponding to the first etch mask patterns can be maintained. Second etch mask patterns are formed in spaces defined by the auxiliary film between adjacent first etch mask patterns. First auxiliary film patterns are formed by removing the auxiliary film formed on the first etch mask patterns. Each first auxiliary film pattern has opposite ends projecting upwardly. The first etch mask patterns and the second etch mask patterns are removed. Second auxiliary film patterns are formed by etching between the ends of the first auxiliary film patterns such that the opposite ends of the first auxiliary film patterns are isolated from each other.

### CROSS-REFERENCES TO RELATED APPLICATIONS

The present application claims priority to Korean patent application number 10-2007-140240, filed on Dec. 28, 2007, which is incorporated by reference in its entirety.

### BACKGROUND OF THE INVENTION

The present invention relates to a method of forming patterns of a semiconductor device and, more particularly, to a method of forming patterns of a semiconductor device, in which the patterns can be formed in two regions with a different pattern density using a common process.

A plurality of elements, such as gates and isolation layers, are commonly formed in a semiconductor substrate. Metal lines for electrically connecting the gates are also formed in the semiconductor substrate. Junction regions (for example, sources or drains of transistors) of the metal lines and the semiconductor substrate are electrically connected by a contact plug.

The gates, metal lines, and the like, are generally formed by a pattern formation process. That is, a target etch layer (for example, a gate stack layer, a conductive layer or a dielectric layer) for patterning are formed over the semiconductor substrate and an etch mask pattern is formed over the target etch layer. The target etch layer is patterned by an etch process employing the etch mask pattern. The formation of micro patterns through this patterning process is indispensable in forming ultra-miniature and high-performance semiconductor devices.

However, the size of a pattern is limited due to the difficulty in overcoming the limit of an apparatus used for the pattern formation process. Further, a difference in the height of photoresist patterns for patterning the target etch layers may occur according to the density and locations of the patterns even though the patterns are formed at the same time. This height difference scatters exposure light in a subsequent pattern formation process since a step is formed on a top surface of a film formed on the photoresist patterns, resulting in an irregular pattern.

### BRIEF SUMMARY OF THE INVENTION

The present invention is directed towards a method of forming patterns of a semiconductor device in which photoresist patterns can be formed without defects irrespective of the density and locations of the patterns by making the height of the patterns substantially the same.

Further, the present invention is directed towards a method of forming patterns of a semiconductor device. Auxiliary film patterns have opposite ends projecting upwardly. Second etch mask patterns are formed between first etch mask patterns formed by the highest resolution of an exposure apparatus. The first and second etch mask patterns are removed. Patterns are then formed by etching between the ends of the auxiliary film patterns, thereby forming more micro patterns than the highest resolution of the exposure apparatus.

A method of forming patterns of a semiconductor device according to a first aspect of the present invention includes forming first etch mask patterns over a semiconductor substrate An auxiliary film is formed over the first etch mask patterns to a thickness in which a step corresponding to the first etch mask patterns can be maintained. Second etch mask patterns are formed in spaces between the auxiliary films formed on sidewalls of the first etch mask patterns. First auxiliary film patterns are formed by removing the auxiliary film formed on the first etch mask patterns. The first auxiliary film patterns have opposite ends projecting upwardly. The first etch mask patterns and the second etch mask patterns are removed. Second auxiliary film patterns are formed by etching between the ends of the first auxiliary film patterns so that the opposite ends of the first auxiliary film patterns are isolated from each other.

The formation of the first etch mask patterns may include: forming hard mask films over the semiconductor substrate, forming an ARC (Anti-Reflective Coating) film over the hard mask film, forming photoresist patterns over the ARC film, and forming ARC film patterns. The first etch mask patterns include the photoresist patterns by etching the ARC film through an etch process employing the photoresist patterns.

Each of the hard mask films may include a stack layer of a first transparent hard mask film and a second transparent hard mask film. The first hard mask film may include a Spin On Carbon (SOC) film or an amorphous carbon film. The second hard mask film may include a Si-containing Bottom Anti-Reflection Coating (BARC) film or a SiON film. The auxiliary film may include an oxide film. The oxide film may be formed in a temperature range of 20 to 150 degrees Celsius. The formation of the second etch mask patterns may include forming a third hard mask film over the auxiliary film, and forming the second etch mask patterns by etching the third hard mask film until the auxiliary film is exposed such that the third hard mask film remains in the spaces between the auxiliary films formed on the sidewalls of the first etch mask patterns. The third hard mask film may include an ARC film. A pitch of the second auxiliary film patterns may be approximately half a pitch of the first etch mask patterns.

A method of forming patterns of a semiconductor device according to a second aspect of the present invention includes forming a target etch layer on a semiconductor substrate including a first region and a second region. The second region includes patterns that are wider than patterns than are formed in the first region. A first etch mask film is formed in the second region and first etch mask patterns are formed in the first region using the first etch mask film. An auxiliary film is formed over the semiconductor substrate to a thickness in which a step corresponding to the first etch mask patterns can be maintained. Second etch mask patterns are formed. The second etch mask patterns include first patterns formed in spaces between the auxiliary films formed on sidewalls of the first etch mask patterns in the first region, and second patterns formed on the auxiliary film in the second region. The auxiliary film formed on the first etch mask patterns is removed. An etch process is performed to remove the first and second etch mask patterns while patterning the first etch mask film of the second region. Opposite ends of the auxiliary film are isolated from each other by removing a central portion of the auxiliary films remaining in the first region.

The formation of the first etch mask patterns may include forming hard mask films over the semiconductor substrate, forming an ARC film over the hard mask films, forming a photoresist film in the second region, forming first photoresist patterns as the photoresist films in the first region, and forming ARC film patterns. The first etch mask patterns include the first photoresist patterns by etching the ARC film of the first region through an etch process employing the first photoresist patterns.

Each of the hard mask films may include a stack layer including a first transparent hard mask film and a second transparent hard mask film. The first hard mask film may include a SOC film or an amorphous carbon film. The second hard mask film may include a Si-containing BARC film or a SiON film. The auxiliary film may include an oxide film. The oxide film may be formed in a temperature range of 20 to 150 degrees Celsius. The formation of the second etch mask patterns may include forming a third hard mask film over the auxiliary film, forming second photoresist patterns over the third hard mask film of the second region, and forming the first patterns in the first region and the second patterns in the second region by etching the third hard mask film until the auxiliary film is exposed through an etch process employing the second photoresist patterns. The third hard mask film may include the ARC film. A pitch of opposite ends of the isolated auxiliary film may be approximately half of a pitch of the first etch mask patterns.

### BRIEF DESCRIPTION OF THE DRAWINGS

FIGS. 1A to 1I are sectional views illustrating a method of forming semiconductor device patterns according to an embodiment of the present invention.

### DESCRIPTION OF SPECIFIC EMBODIMENTS

An embodiment according to the present invention will be described with reference to the accompanying drawings. However, the present invention is not limited to the disclosed embodiment, but may be implemented in various configurations. The embodiment is provided to complete the disclosure of the present invention and to allow those having ordinary skill in the art to understand the present invention. The present invention is defined by the scope of the claims.

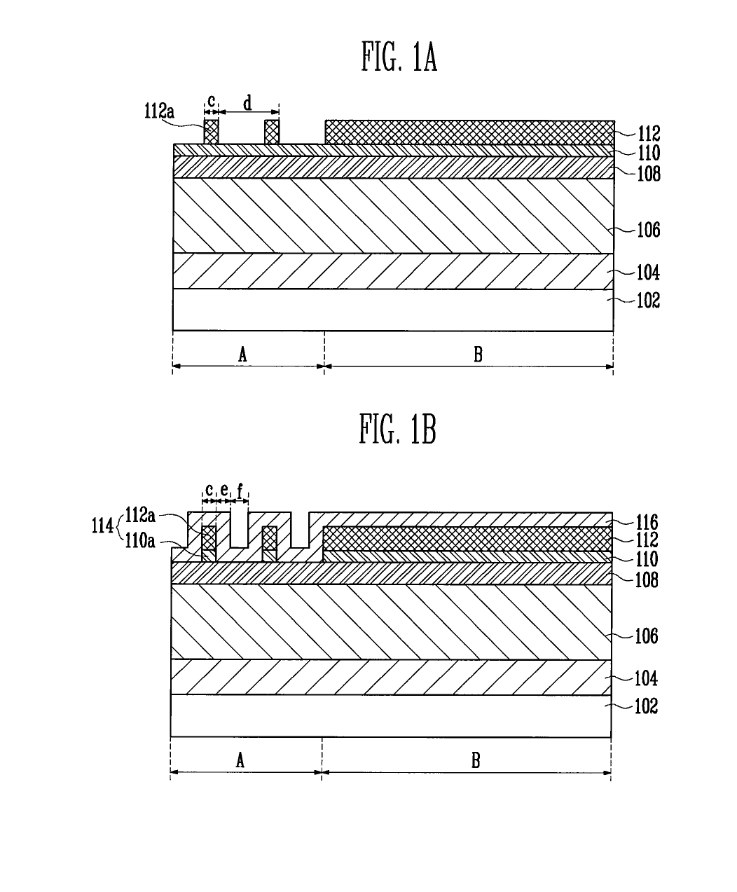

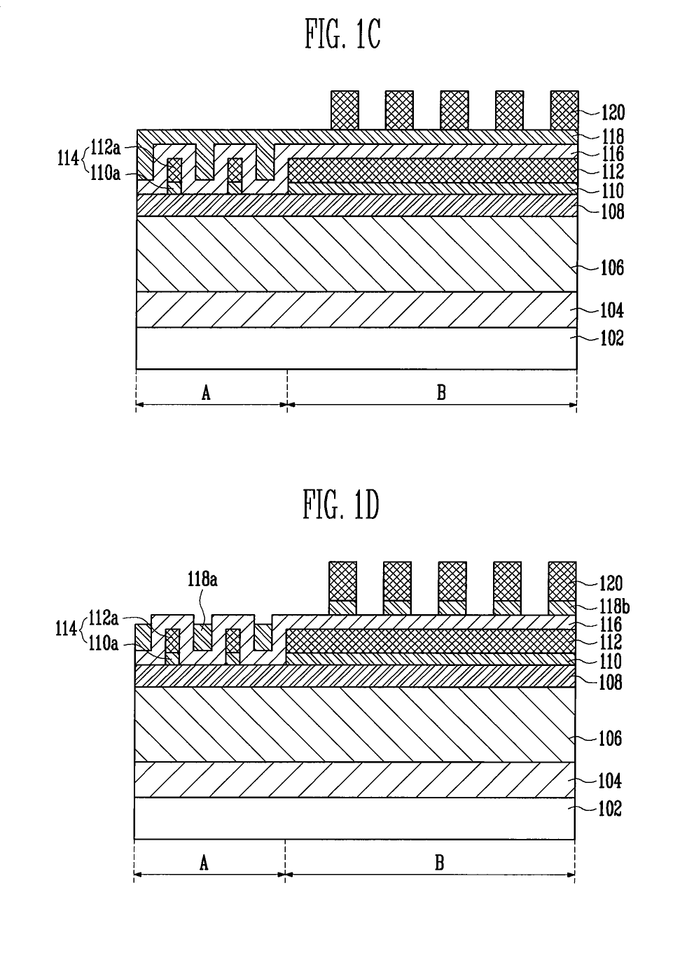

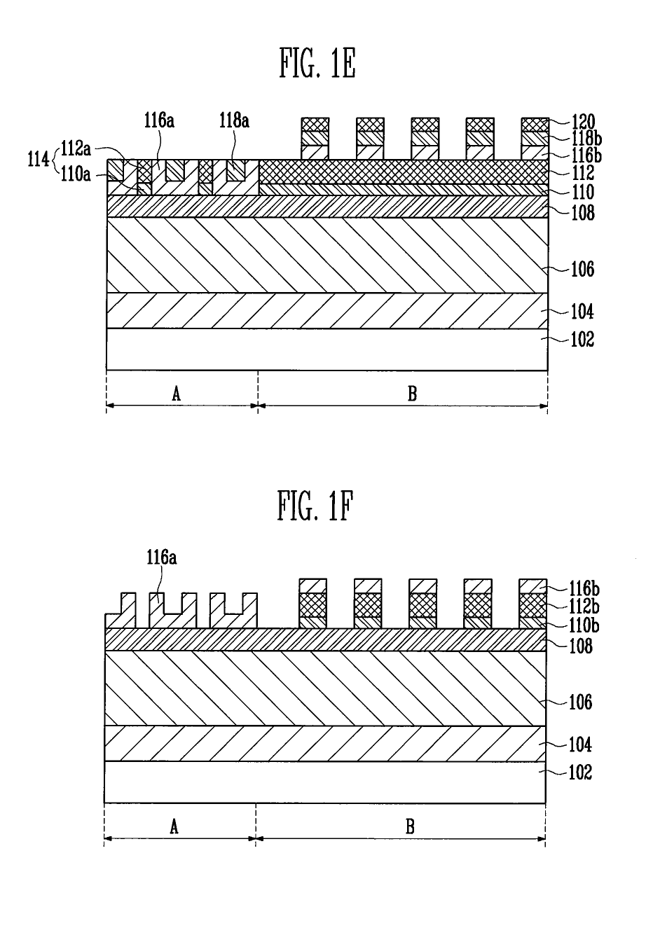

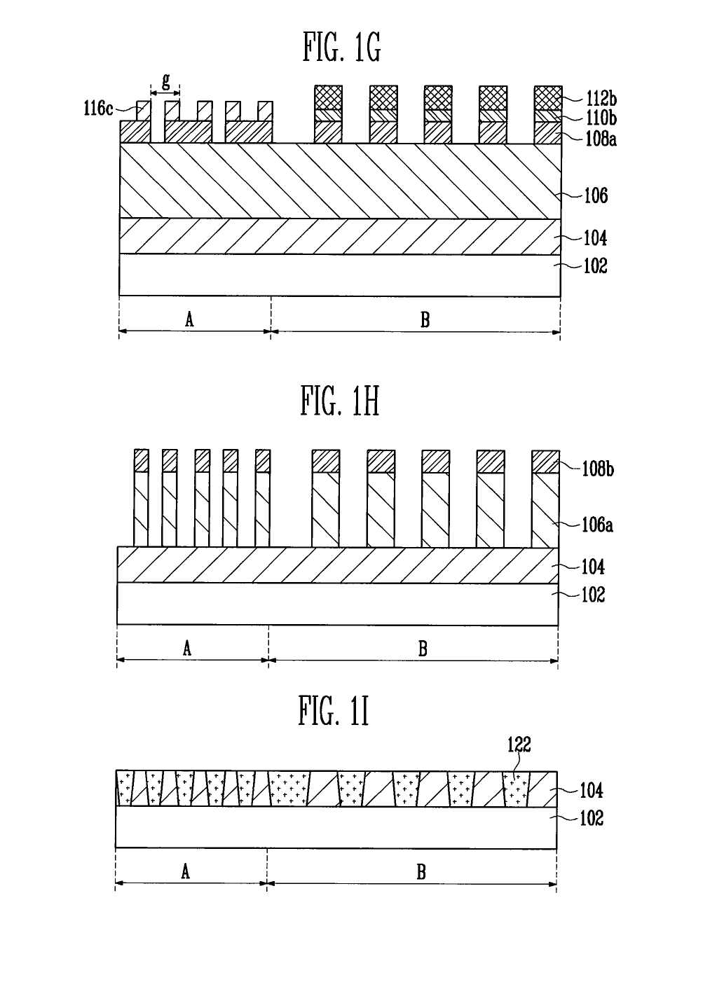

FIGS. 1A to 1I are sectional views illustrating a method of forming semiconductor device patterns according to an embodiment of the present invention.

Referring to FIG. 1A, a target etch layer 104 is formed on a semiconductor substrate 102. The target etch layer 104 includes a first region A in which specific patterns are formed and a second region B in which patterns having a wider pitch than that of the first region are formed. The first region A can be a cell region in a flash memory device and the second region B can be a peri region in a flash memory device. Metal lines connected to gates, junction regions or contact plugs formed in the semiconductor substrate 102 can be formed by forming the target etch layer 104 using an insulating layer, forming specific patterns in the target etch layer 104 and gap-filling the patterns with conductive material.

A hard mask film for patterning the target etch layer 104 is formed on the target etch layer 104. The hard mask film may include two or more stack layers (for example, a first hard mask film 106 and a second hard mask film 108) having a transparent property. The first hard mask film 106 can be formed of a Spin On Carbon (SOC) film or an amorphous carbon film. The second hard mask film 108 can be formed of a Si-containing Bottom Anti-Reflective Coating (BARC) film or a SiON film.

An ARC film 110 is formed on the second hard mask film 108. The ARC film 110 prevents irregular patterns from being formed due to diffused reflection in a subsequent exposure process.

A photoresist film 112 is formed on the ARC film 110. First photoresist patterns 112a are formed in the first region A through exposure and development processes. A pitch “d” of the first photoresist patterns 112a can be approximately twice as large as that of target patterns to be formed in the target etch layer 104. To this end, the pitch “d” of the first photoresist patterns 112a formed in the first region A may be approximately three times larger than a width “c” of the first photoresist pattern 112a.

The surface of a film to be formed on the first photoresist patterns 112a in a subsequent process can be made to be flat with no step in the first region A and the second region B due to the existence of the photoresist film 112 in the second region B.

Referring to FIG. 1B, the ARC film 110 is patterned using the first photoresist patterns 112a as an etch mask. Thus, first etch mask patterns 114, including the first photoresist patterns 112a and the ARC film pattern 110a, are formed in the first region A.

An auxiliary film 116 is formed on sidewalls and a top surface of the first etch mask patterns 114 formed in the first region A, and on the photoresist film 112 formed in the second region B. The auxiliary film 116 can be formed to a thickness of a degree in which a step formed by the first etch mask patterns 114 can be maintained. Specifically, a thickness “e” of the auxiliary film 116 may be substantially identical to the width “c” of the first etch mask pattern 114. Further, a distance “f” between the auxiliary films 116 formed in the first etch mask patterns 114 may be substantially identical to the thickness “e” of the auxiliary film 116.

This embodiment is concerned with the formation of target patterns in which the width of the pattern is essentially identical to a distance between the patterns and the pitch of the pattern is approximately half the pitch of the first etch mask patterns 114 formed in the first region A. Accordingly, it is to be understood that the present invention can be applied to a specific process of forming patterns having a pitch smaller than that of the first etch mask patterns 114 formed in the first region A. In this case, the width “c” of the first etch mask pattern 114, the pitch “d” of the first etch mask patterns 114, the thickness “e” of the auxiliary film 116, and the distance “f” of the auxiliary film 116 may be varied.

The auxiliary film 116 can be formed using a dielectric layer (for example, an oxide film) at a low temperature so as to prevent the first photoresist patterns 112a from being damaged. The oxide film may be formed at a normal temperature (for example in a temperature range of 20 to 150 degrees Celsius).

Referring to FIG. 1C, a third hard mask film 118 is formed on the auxiliary film 116. The third hard mask film 118 prevents irregular patterns from being formed due to diffused reflection in a subsequent exposure process. The third hard mask film 118 may be formed using the same material as that of the ARC film 110 to facilitate a subsequent etch process.

In the above process, the photoresist film 112 is also formed in the second region B, such that a top surface of the third hard mask film 118 can be made to be flat. In other words, if the photoresist film 112 is not formed in the second region B unlike an embodiment of the present invention, a big step would exist between the surface of the first region A and the surface of the second region B due to the first etch mask patterns 114. In this case, if the third hard mask film 118 is formed on the top surface, the thickness of the third hard mask film 118 is larger in the first region A than in the second region B. Thus, an inclined surface is formed on the third hard mask film 118 between the first region A and the second region B. This inclined surface may cause a notching phenomenon in which exposure light reaching the first region A and the second region B in a subsequent process is distorted, resulting in irregular patterns.

Second photoresist patterns 120 for forming target patterns to be formed in the second region B of the target etch layer 104 are formed on the third hard mask film 118 of the second region B. The second photoresist patterns 120 may correspond to the target patterns formed in the second region B of the target etch layer 104.

Referring to FIG. 1D, the third hard mask film 118 is etched and patterned by an etch process using the second photoresist patterns 120 as an etch mask until the auxiliary film 116 is exposed. The etch process may be performed under conditions in which the etched amount of the auxiliary film 116 is small relative to the third hard mask film 118. Hence, second etch mask patterns 118a (i.e., ARC film patterns) are formed in the first region A between the auxiliary films 116 formed between the first etch mask patterns 114. Third hard mask film patterns 118b are also formed in the second region B along the second photoresist patterns 120.

Referring to FIG. 1E, the auxiliary film 116 is etched until the first etch mask pattern 114 and the photoresist film 112 are exposed. Accordingly, the auxiliary film 116 of the first region A becomes first auxiliary film patterns 116a having opposite ends projecting upwardly. Auxiliary film patterns 116b are formed in the second region B along the second photoresist patterns 120.

Referring to FIG. 1F, the first photoresist patterns 112a of the first region A and the second photoresist patterns 120 of the second region B are removed by performing a typical etch process on the photoresist. Third photoresist patterns 112b are then formed by patterning the photoresist film 112 of the second region B. Thereafter, the ARC film pattern 110a and the second etch mask patterns 118a of the first region A are removed by performing a typical etch process on the ARC film. ARC film patterns 110b are then formed by pattering the ARC film 110 exposed in the second region B.

Accordingly, the first auxiliary film patterns 116a are exposed on the second hard mask film 108 of the first region A. The auxiliary film patterns 116b, the third photoresist patterns 112b and the ARC film patterns 110b are formed over the second hard mask film 108 of the second region B.

Referring to FIG. 1G, an anisotropic etch process is performed on the first auxiliary film patterns 116a. The auxiliary film patterns 116b of the second region B are removed. The first auxiliary film patterns 116a of the first region A are etched such that second auxiliary film patterns 116c are formed. A pitch “g” of the second auxiliary film patterns 116c may be approximately half the pitch “d” of the first photoresist patterns 112a in the previous process. Accordingly, target patterns, which are approximately twice the resolution of an apparatus for forming patterns, can be formed. Part of the exposed second hard mask film 108 is also patterned, thereby forming second hard mask patterns 108a.

Referring to FIG. 1H, the second hard mask patterns 108a of the first region A are patterned by an etch process using the second auxiliary film patterns 116c of the first region A as an etch mask. Thus, second hard mask patterns 108b having a pitch that is much smaller than those of the second region B are formed on the first hard mask film 106 of the first region A. First hard mask patterns 106a are formed by etching the first hard mask film 106 using an etch process employing the second hard mask patterns 108b. In this process, the second auxiliary film patterns 116c, the first photoresist patterns 112a and the ARC film patterns 150b are removed. The process of forming the third etch mask patterns 118b to the process of forming the first hard mask patterns 106a, which correspond to FIG. 1D, can be performed in-situ.

Referring to FIG. 1I, trenches are formed by etching the target etch layer 104 through an etch process employing the second hard mask patterns 108b and the first hard mask patterns 106a. Conductive material (for example, tungsten (W) or copper (Cu)) is formed on the target etch layer 104 including the trenches to gap fill the trenches. Metal lines 122 are formed in the target etch layer 104 by performing a polishing process, such as Chemical Mechanical Polishing (CMP), on the conductive material formed on the target etch layer 104. The second hard mask patterns 108b and the first hard mask patterns 106 are removed. The metal lines 122 can be connected to gates, junction regions or contact plugs formed in the semiconductor substrate 102.

As described above, according to the present invention, patterns without defects can be formed by forming the height of photoresist patterns that is substantially identical irrespective of the locations of the patterns. Furthermore, in accordance with the present invention, more micro patterns than the highest resolution of an exposure apparatus can be formed.

The embodiment disclosed herein has been proposed to allow a person skilled in the art to easily implement the present invention. However, the present invention is not limited by or to the embodiment as described above, and should be construed to be defined only by the scope of the appended claims and their equivalents.

What is claimed is:

1. A method of forming patterns of a semiconductor device, the method comprising:
forming first etch mask patterns over a semiconductor substrate;
forming an auxiliary film over the first etch mask patterns to a thickness in which a step corresponding to the first etch mask patterns can be maintained, wherein the auxiliary film is formed on sidewalls of the first etch mask patterns and defines a space between adjacent first etch mask patterns;
forming a second etch mask pattern in each space defined by the auxiliary film;
removing the auxiliary film formed over the first etch mask patterns to form first auxiliary film patterns, the first auxiliary film patterns having opposite ends projecting vertically;
removing the first etch mask patterns and the second etch mask patterns; and
etching between the ends of the first auxiliary film patterns to form second auxiliary film patterns, wherein the ends of the first auxiliary film patterns are isolated from each other.

2. The method of claim 1, wherein forming the first etch mask patterns comprises:
forming hard mask films over the semiconductor substrate;
forming an Anti-Reflective Coating (ARC) film over the hard mask film;
forming photoresist patterns over the ARC film;
forming ARC film patterns, and etching the ARC film through an etch process employing the photoresist patterns such that the first etch mask patterns include the photoresist patterns.

3. The method of claim 2, wherein each of the hard mask films comprises a stack layer comprising a first transparent hard mask film and a second transparent hard mask film.

4. The method of claim 3, wherein the first hard mask film comprises a Spin On Carbon (SOC) film or an amorphous carbon film.

5. The method of claim 3, wherein the second hard mask film comprises a Si-containing Bottom Anti-Reflection Coating (BARC) film or a SiON film.

6. The method of claim 1, wherein the auxiliary film comprises an oxide film.

7. The method of claim 6, wherein the oxide film is formed in a temperature range of 20 to 150 degrees Celsius.

8. The method of claim 1, wherein forming the second etch mask patterns comprises:
forming a third hard mask film over the auxiliary film; and
etching the third hard mask film until the auxiliary film is exposed to form the second etch mask patterns, wherein the third hard mask film remains in the spaces defined by the auxiliary film between the adjacent first etch mask patterns.

9. The method of claim 8, wherein the third hard mask film comprises an ARC film.

10. The method of claim 1, wherein a pitch of the second auxiliary film patterns is approximately half a pitch of the first etch mask patterns.

11. A method of forming patterns of a semiconductor device, the method comprising:
forming a target etch layer over a semiconductor substrate including a first region and a second region, wherein the second region comprises patterns that are wider than patterns formed in the first region;
forming a first etch mask film in the second region;
forming first etch mask patterns in the first region using the first etch mask film;
forming an auxiliary film over the first etch mask patterns and the first etch mask film, wherein the auxiliary film is formed to a thickness in which a step corresponding to the first etch mask patterns can be maintained, the auxiliary film being formed on sidewalls of the first etch mask patterns and defining a space between adjacent first etch mask patterns in the first region;
forming second etch mask patterns, wherein the second etch mask patterns comprise:
first patterns formed in the spaces defined by the auxiliary film between the adjacent first etch mask patterns in the first region, and
second patterns formed over the auxiliary film in the second region;
removing the auxiliary film formed over the first etch mask patterns to form auxiliary film patterns in the first region, wherein each auxiliary film pattern comprises opposite ends projecting vertically;
performing an etch process to remove the first and second etch mask patterns, wherein the etch process patterns the first etch mask film of the second region; and
removing a central portion of each auxiliary film pattern in the first region to isolate the opposite ends of each auxiliary film pattern from each other.

12. The method of claim 11, wherein forming the first etch mask patterns comprises:
forming hard mask films over the semiconductor substrate;
forming an ARC film over the hard mask films;
forming a photoresist film in the second region;
forming first photoresist patterns as the photoresist films in the first region;
forming ARC film patterns; and
etching the ARC film of the first region through an etch process employing the first photoresist patterns such that the first etch mask patterns include the first photoresist patterns.

13. The method of claim 12, wherein each of the hard mask films comprise a stack layer including a first transparent hard mask film and a second transparent hard mask film.

14. The method of claim 13, wherein the first transparent hard mask film comprises a SOC film or an amorphous carbon film.

15. The method of claim 13, wherein the second transparent hard mask film comprises a Si-containing BARC film or a SiON film.

16. The method of claim 11, wherein the auxiliary film comprises an oxide film.

17. The method of claim 16, wherein the oxide film is formed in a temperature range of 20 to 150 degrees Celsius.

18. The method of claim 11, wherein forming the second etch mask patterns comprises:
forming a third hard mask film over the auxiliary film;
forming second photoresist patterns over the third hard mask film of the second region; and
etching the third hard mask film until the auxiliary film is exposed using an etch process employing the second photoresist patterns, wherein the first patterns are formed in the first region and the second patterns are formed in the second region.

19. The method of claim 18, wherein the third hard mask film comprises an ARC film.

20. The method of claim 11, wherein a pitch of the opposite ends of each isolated auxiliary film pattern is approximately half a pitch of the first etch mask patterns.

21. The method of claim 11, wherein forming the second etch mask patterns by removing a central portion of each auxiliary film pattern is performed in-situ.

22. A method of forming patterns of a semiconductor device, the method comprising:
forming first etch mask patterns over a first region of a semiconductor substrate and forming an etch mask film over a second region of the semiconductor substrate;
forming an auxiliary film over the first etch mask patterns and the first etch mask film, wherein the auxiliary film is formed to have a thickness in which a step corresponding to the first etch mask patterns can be maintained, the auxiliary film being formed on sidewalls of the first etch mask patterns and defining a space between adjacent first etch mask patterns;
forming second etch mask patterns in the first region and in the second region, wherein:
the second etch mask patterns in the first region are formed in the spaces defined by the auxiliary film between the adjacent first etch mask patterns, and
the second etch mask patterns in the second region are formed over the auxiliary film;
removing the auxiliary film formed in the first region to form auxiliary film patterns, each auxiliary film pattern having vertically projecting opposite ends;
removing the first etch mask patterns and the second etch mask patterns; and
etching between the opposite ends of each auxiliary film pattern such that the opposite ends of each auxiliary film patterns are isolated from each other.
